(19) United States
(12) Patent Application Publication
(10) Pub. No.: US 2023/0284453 A1
(43) Pub. Date: Sep. 7, 2023

(54) SEMICONDUCTOR STRUCTURE AND METHOD FOR MANUFACTURING SAME

(71) Applicant: CHANGXIN MEMORY TECHNOLOGIES, INC., Hefei City (CN)

(72) Inventor: Wei Chang, Hefei (CN)

(73) Assignee: CHANGXIN MEMORY TECHNOLOGIES, INC., Hefei City (CN)

(21) Appl. No.: 17/861,952

(22) Filed: Jul. 11, 2022

Related U.S. Application Data
(63) Continuation of application No. PCT/CN2022/088945, filed on Apr. 25, 2022.

(30) Foreign Application Priority Data
Mar. 7, 2022 (CN) 202210216344.0

(51) Int. Cl. H01L 27/1159; H01L 27/11587; H01L 29/66; H01L 29/78; H01L 29/792

(52) U.S. Cl. CPC H01L 27/1159; H01L 27/11587; H01L 29/6684; H01L 29/78391; H01L 29/66833; H01L 29/792

(57) ABSTRACT

A semiconductor structure includes a gate dielectric layer and a gate located on a surface of the gate dielectric layer, in which the gate dielectric layer includes an oxide layer, a charge trapping layer and an isolation layer stacked in sequence, and the isolation layer is made of a polarization material capable of spontaneous polarization.

### CROSS-REFERENCE TO RELATED APPLICATIONS

The present application is a U.S. continuation application of International Application No. PCT/CN2022/088945, filed on Apr. 25, 2022, which claims priority to Chinese Patent Application No. 202210216344.0, filed on Mar. 7, 2022. International Application No. PCT/CN2022/088945 and Chinese Patent Application No. 202210216344.0 are incorporated herein by reference in their entirety.

### BACKGROUND

Nowadays, a silicon-oxide-nitride-oxide-silicon (SONOS) flash memory and a ferroelectric field effect transistor (FeFET) memory are the two most promising memories.

The SONOS memory is composed of a silicon substrate, a tunneling oxide layer, a charge storage layer of silicon nitride, a blocking oxide layer and a polysilicon gate. This kind of memory performs compiling by tunneling of electrons and p erases data by implanting holes. The SONOS memory has advantages of a simple process, a low operating voltage and being easily integrated into a standard complementary metal oxide semiconductor (CMOS) process. However, with the continuous shrinking of process nodes of semiconductor devices, the traditional SONOS memory suffers from a poorer retention and serious reliability problems as its size shrinks.

The FeFET memory is composed of a metal electrode, a ferroelectric film, another metal electrode, a buffer layer and a semiconductor conductive channel. By applying a voltage to a gate and adjusting the polarization of electric dipoles in the ferroelectric film, a ferroelectric material in the ferroelectric film has two different polarization states, thereby realizing storages of data “0” and data “1”. The FeFET memory has the advantages of a fast read/write response, low power consumption and non-destructive reading. However, the reliability of the FeFET memory decreases obviously after times of read/write/erasing operations.

### SUMMARY

In view of this, embodiments of the disclosure provide a semiconductor structure and a method for manufacturing the semiconductor structure.

In a first aspect, embodiments of the disclosure provide a semiconductor structure including a gate dielectric layer and a gate located on a surface of the gate dielectric layer, in which the gate dielectric layer includes an oxide layer, a charge trapping layer and an isolation layer stacked in sequence, and the isolation layer is made of a polarization material capable of spontaneous polarization.

In a second aspect, an embodiment of the disclosure provides a method for forming the semiconductor structure, which includes:
forming a gate dielectric layer, in which the gate dielectric layer includes an oxide layer, a charge trapping layer and an isolation layer stacked in sequence, and the isolation layer is made of a polarization material capable of spontaneous polarization; and
forming a gate on a surface of the isolation layer.

### BRIEF DESCRIPTION OF THE DRAWINGS

In the drawings (which are not necessarily drawn to scale), similar reference numerals can describe similar components in different views. Similar reference numerals with different letter suffixes may represent different examples of similar components. The various embodiments discussed herein are generally shown in the accompanying drawings by an exemplary way rather than a limitative way.

FIG. 1 is a structural schematic diagram of a semiconductor structure provided by embodiments of the disclosure;

FIG. 2 is a schematic diagram of an working principle of an semiconductor structure provided by embodiments of the disclosure;

FIG. 3 is a schematic diagram of an working principle of an semiconductor structure provided by embodiments of the disclosure;

FIG. 4 is another structural schematic diagram of a semiconductor structure provided by embodiments of the disclosure;

FIG. 5A is a cross-sectional view of a semiconductor structure provided by embodiments of the disclosure;

FIG. 5B is a top view of a semiconductor structure provided by embodiments of the disclosure;

FIG. 6 is a flowchart of a method for manufacturing a semiconductor structure provided by embodiments of the disclosure;

FIG. 7A is a schematic structural diagram corresponding to semiconductor forming procedures provided by embodiments of the disclosure;

FIG. 7B is a schematic structural diagram corresponding to semiconductor forming procedures provided by embodiments of the disclosure;

FIG. 7C is a schematic structural diagram corresponding to semiconductor forming procedures provided by embodiments of the disclosure;

FIG. 7D is a schematic structural diagram corresponding to semiconductor forming procedures provided by embodiments of the disclosure;

FIG. 7E is a schematic structural diagram corresponding to semiconductor forming procedures provided by embodiments of the disclosure;

FIG. 7F is a schematic structural diagram corresponding to semiconductor forming procedures provided by embodiments of the disclosure;

FIG. 7G is a schematic structural diagram corresponding to semiconductor forming procedures provided by embodiments of the disclosure; and

FIG. 7H is a schematic structural diagram corresponding to semiconductor forming procedures provided by embodiments of the disclosure.

### DETAILED DESCRIPTION

The disclosure relates to the technical field of semiconductors, and relates to, but is not limited to a semiconductor structure and a method for manufacturing the semiconductor structure.

Exemplary embodiments of the disclosure will be described in more detail below with reference to the accompanying drawings. Although exemplary embodiments of the disclosure are shown in the drawings, it should be understood that the disclosure may be implemented in various forms and should not be limited by the specific embodiments set forth here. On the contrary, these embodiments are provided for a more thorough understanding of the disclosure, and to fully convey the scope of this disclosure to those skilled in the art.

In the following description, numerous specific details are set forth in order to provide the more thorough understanding of the disclosure. However, it will be apparent to those skilled in the art that the disclosure may be implemented without one or more of these details. In other embodiments, in order to avoid being confused with this disclosure, some technical features well known in the art are not described. That is, not all features of actual embodiments are described, and well-known functions and structures are not described in detail.

In the drawings, the dimensions of layers, regions/areas, elements and their relative dimensions may be amplified for clarity. The same reference numeral indicate that same elements throughout.

It should be understood that when an element or layer is referred to as being on, adjacent to, connected to or coupled to another element or layer, it may be directly on, adjacent to, connected to or coupled to the element or layer, or an interval element or layer may exist. On the contrary, when an element is referred to as directly on, directly adjacent to, directly connected to or directly coupled to another element or layer, there is no interval element or layer. It should be understood that although the terms first, second, third, etc. may be used to describe various elements, components, regions/areas, layers and/or parts, these elements, components, areas, layers and/or parts should not be limited by these terms. These terms are only used to distinguish one element, component, region/area, layer or part from another element, component, region/area, layer or part. Therefore, without departing from the teaching of the disclosure, the first element, component, region/area, layer or part discussed below may be indicated as a second element, component, region/area, layer or part. When the second element, component, region/area, layer or part is discussed, it does not mean that the first element, component, region/area, layer or part certainty exists in the disclosure.

The terms used here are only for the purpose of describing specific embodiments and should not be taken as a limitation on the disclosure. As used herein, singular forms of “a/an”, “one” and “said/the” are also intended to include plural forms, unless the context clearly dictates otherwise. It should also be understood that the terms “constitute” and/or “include”, when used in this specification, identify the presence of stated feature, integer, step, operation, element and/or component, but do not exclude the presence or addition of one or more other features, integers, steps, operations, elements, components and/or groups. As used herein, the term “item and/or” includes any and all combinations of related listed items.

As the SONOS memory in the related art has problems of poor retentivity and reliability when the process nodes are shrinking continuously, and the FeFET memory in the related art has the problem of obvious decrease in reliability after a plurality of read/write/erase operations, embodiments of the disclosure provide a novel semiconductor device with a low working voltage, low power consumption and high reliability by combining technologies of the SONOS memory and the FeFET memory.

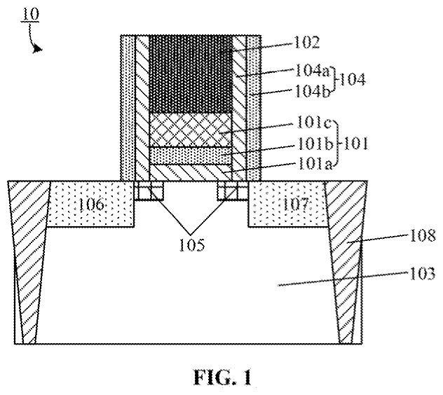

FIG. 1 is a structural schematic diagram of a semiconductor structure provided by embodiments of the disclosure. As shown in FIG. 1, the semiconductor structure 10 includes a gate dielectric layer 101 and a gate 102 located on the surface of the gate dielectric layer.

The gate dielectric layer 101 includes an oxide layer 101a, a charge trapping layer 101b and an isolation layer 101c stacked in sequence. The isolation layer 101c is made of a polarization material capable of spontaneous polarization. The gate 102 is located on the surface of the isolation layer 101c. The oxide layer 101a may be a high-k material layer, which can improve an effective oxide thickness (EOT) of the gate dielectric layer 101. For example, the material of the oxide layer 101a may include at least one of hafnium oxide (HfO₂) or silicon oxide. The charge trapping layer 101b may be any material layer capable of trapping electrons, such as a silicon nitride layer, that is, the charge trapping layer 101b may be made of silicon nitride. The polarization material includes a ferroelectric oxide, a ferroelectric fluoride, a ferroelectric semiconductor material, a doped ferroelectric oxide, a polymer ferroelectric material or any combination thereof.

In the embodiments of the disclosure, the thickness of the isolation layer in a direction perpendicular to a plane of a substrate is greater than 1 nanometer. The isolation layer is used for preventing electrons from tunneling between the gate and the charge trapping layer, and assisting the electrons to enter or leave the charge trapping layer. As a result, the working voltage of the semiconductor structure can be reduced, and the retention characteristic and durability of the semiconductor structure can be improved.

In some embodiments, the gate of the semiconductor structure may be a planar gate structure. Again, referring to FIG. 1, the semiconductor structure 10 further includes the substrate, which includes an active area (only one well region in the active region is shown in FIG. 1). The gate dielectric layer 101 is located on the surface of the well region 103, and the gate dielectric layer 101 includes the oxide layer 101a, the charge trapping layer 101b and the isolation layer 101c stacked in order from bottom to top.

In the embodiments of the disclosure, the well region is a region formed by performing an N-type doping process or a P-type doping process on the substrate (e.g. a silicon substrate) of the semiconductor, and is used for forming a transistor.

In some embodiments, again, referring to FIG. 1, the semiconductor structure 10 further includes a spacer structure 104. The spacer structure 104 is located at sidewalls of the gate dielectric layer 101 and the gate 102, and includes a first spacer layer 104a and a second spacer layer 104b outside the first spacer layer 104a.

In the embodiments of the disclosure, the material of the first spacer layer may be silicon oxide or a low-k material, and the low-k material can improve the coupling parasitic capacitance between the gate and the source/drain. The material of the second spacer layer may be any insulating material, which can protect the gate when the source and drain are being doped. For example, the material of the second spacer layer may be silicon nitride.

In some embodiments, again, referring to FIG. 1, the semiconductor structure 10 further includes lightly doped drain implanted regions 105 located in the well region 103 at the bottom of the gate dielectric layer 101.

In some embodiments, again, referring to FIG. 1, the semiconductor structure 10 further includes a source 106 and a drain 107. The source 106 and drain 107 are located in the well region outside the lightly doped drain implanted regions 105, and symmetrically distributed with respect to the gate structure.

In embodiments of the disclosure, the existence of lightly doped drain implanted regions, on one hand prevents short channel effect caused as the width of a gate and channel length corresponding to the gate decrease continuously, and on the other hand reduces the channel leakage current between a source and a drain.

In some embodiments, again, referring to FIG. 1, the semiconductor structure 10 further includes a shallow trench isolation region 108. A plurality of well regions 103 are isolated from each other by the shallow trench isolation regions 108.

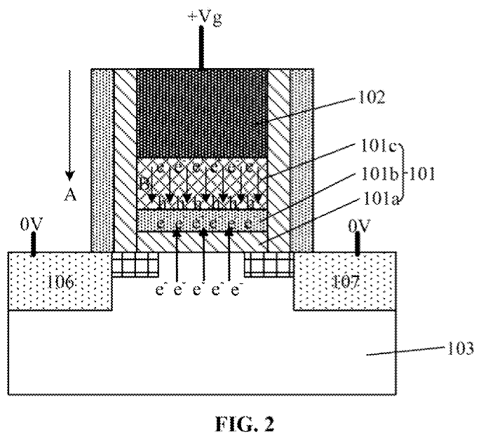

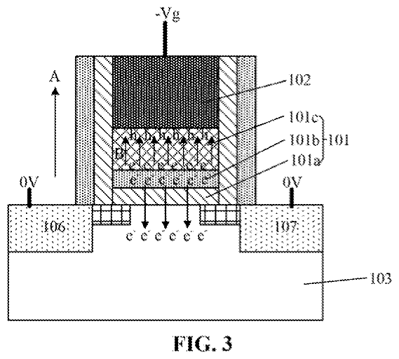

FIGS. 2 and 3 are schematic diagrams of a working principle of a semiconductor structure provided by embodiments of the disclosure, and the working principle of the semiconductor structure provided by the embodiments of the disclosure will be illustrated below with reference to FIGS. 2 and 3.

As shown in FIG. 2, if a positive working voltage Vg is applied to the gate 102, electrons in the well region 103 tunnel through the oxide layer 101a and enter the charge trapping layer 101b under an external electric field A generated by the gate voltage, and are trapped by deep level traps in the charge trapping layer 101b, thereby realizing a programming operation. Before the programming operation, due to a spontaneous polarization effect of the isolation layer 101c, the electrons and holes in the isolation layer are separated. During the programming operation, under the external electric field A, the polarization direction of the isolation layer 101c gradually is the same as the direction of the external electric field A, resulting in a polarization electric field B. The external electric field A and the polarization electric field B jointly control the electrons in the well region 103 to tunnel into the charge trapping layer 101b.

In the embodiments of the disclosure, because the existence of the isolation layer can generate an additional polarization electric field that has the same direction as the external electric field generated by the gate voltage, the polarization electric field can control and help the electrons in the well region to transition into the charge trapping layer. That is to say, the existence of the polarization electric field can enhance the tunneling ability of the electrons. Therefore, if the semiconductor structure includes the isolation layer, the working voltage of the programming operation is smaller, and the durability of the semiconductor structure is good. As a result, a possible damage to a tunneling layer caused by a high voltage is reduced, and implanted electrons or holes can reach a longer distance into the substrate, so that the retention property of the electrons or holes is good, and a possible leakage path is longer, and a leakage in one read/write operation is less.

As shown in FIG. 3, if a negative working voltage Vg is applied to the gate 102, the electrons trapped in the charge trapping layer 101b, under the action of the external electric field A, escape from the traps, tunnel through the oxide layer 101a and are implanted into the well region 103. Alternatively, holes in the well region 103, under the action of the external electric field A, tunnel through the oxide layer 101a, enter the charge trapping layer 101b and recombine with the electrons trapped in the charge trapping layer 101b to realize an erasing operation. Before the erasing operation, the electrons and holes are separated due to the spontaneous polarization of the isolation layer 101c. During erasing, under the action of the external electric field A, the polarization direction of the isolation layer 101c gradually is the same as the direction of the external electric field A, resulting in the polarization electric field B. The external electric field A and the polarization electric field B jointly control the electrons of the charge trapping layer 101b to escape into the well region 103. Alternatively, the external electric field A and the polarization electric field B jointly control the holes in the well region 103 to implant into the charge trapping layer 101b and recombine with the electrons trapped in the charge trapping layer 101b.

In the embodiment of the disclosure, because the existence of the isolation layer can generate an additional polarization electric field that has the same direction as the external electric field generated by the gate voltage, the polarization electric field can control the electrons in the charge trapping layer to escape to the well region, or control the holes in the well region to implant into the charge trapping layer. That is to say, the existence of the polarization electric field can enhance the tunneling ability of the electrons or holes. Therefore, if the semiconductor structure includes the isolation layer, the erasing operation can be realized only by applying a smaller negative voltage to the gate. That is to say, the existence of the isolation layer can reduce the erasing voltage of the semiconductor structure and make the semiconductor structure have better retention.

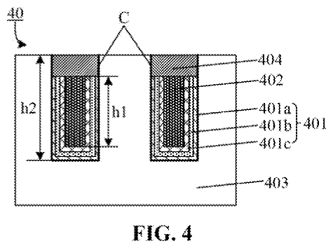

In some embodiments, the gate of the semiconductor structure may also be an embedded gate structure. FIG. 4 is another structural schematic diagram of a semiconductor structure provided by embodiments of the disclosure. As shown in FIG. 4, the semiconductor structure 40 includes a gate dielectric layer 401 and a gate 402 located in the gate dielectric layer 401.

The gate dielectric layer 401 includes an oxide layer 401a, a charge trapping layer 401b and an isolation layer 401c stacked in sequence. The isolation layer 401c is made of a polarization material capable of spontaneous polarization. The gate 402 is located inside the groove formed by the isolation layer 401c.

In embodiments of the disclosure, the polarization material includes the ferroelectric oxide, the ferroelectric fluoride, the ferroelectric semiconductor material, the doped ferroelectric oxide, the polymer ferroelectric material or any combination thereof.

In some embodiments, the semiconductor structure 40 further includes a substrate including a plurality of well regions 403 (only one well region is shown in FIG. 4), and each well region 403 has at least one gate trench C (two gate trenches are shown in FIG. 4) therein. The gate 402 is located in each gate trench C, and the gate dielectric layer 401 is located between the gate 402 and the gate trench C.

Again, referring to FIG. 4, in the embodiments of the disclosure, thickness h1 of the gate 402 is smaller than thickness h2 of the gate trench C in a direction perpendicular to the substrate.

In some embodiments, again, referring to FIG. 4, the semiconductor structure 40 further includes a gate insulation layer 404 on the surface of each gate 402 and each gate dielectric layer 401. The top surface of the gate insulation layer 404 is flush with that of the well region 403. The gate insulation layer 404 is used for isolating the gate structure embedded inside the well region 403 from other functional structures (not shown) located on the surface of the well region 403.

It should be noted that the working principle of the semiconductor structure provided by the embodiments of the disclosure is similar to that of the semiconductor structure with the planar gate structure in the above embodiment, and will not be described in detail here.

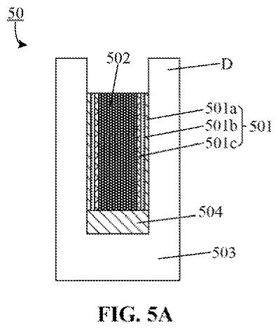

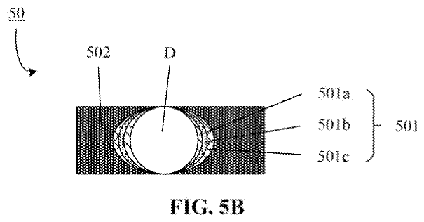

In some embodiments, the gate of the semiconductor structure may also be a full ring gate structure. FIG. 5A is a cross-sectional view of a semiconductor structure provided by embodiments of the disclosure, and FIG. 5B is a top view of the semiconductor structure provided by the embodiments of the disclosure. As shown in FIGS. 5A and 5B, the semiconductor structure 50 includes gate dielectric layers 501 and a gate 502 located in a groove formed by the gate dielectric layers 501.

Each gate dielectric layer 501 includes an oxide layer 501a, a charge trapping layer 501b and an isolation layer 501c stacked in sequence. The isolation layer 501c is made of a polarization material capable of spontaneous polarization, and the gate 502 is located on the surfaces of the isolation layers 501c.

In the embodiment of the disclosure, the polarization material includes the ferroelectric oxide, the ferroelectric fluoride, the ferroelectric semiconductor material, the doped ferroelectric oxide, the polymer ferroelectric material or any combination thereof.

In some embodiments, the semiconductor structure 50 further includes an active region (only one well region in the active region is shown in FIG. 5A), and each well region 503 includes a plurality of active columns D (two active columns are shown in FIG. 5A) isolated from each other. The gate dielectric layer 501 surrounds each active column D, and gates 502 fill gaps between the gate dielectric layers 501.

Again, referring to FIG. 5A, in the embodiments of the disclosure, the top surface of the gate dielectric layer 501 is flush with that of the gate 502, and the top surface of the active column D is beyond that of the gate dielectric layer 501. A portion of the active column D beyond the gate dielectric layer 501 or the gate 502 is used for forming a source or a drain of the semiconductor structure 50. The gate dielectric layer 501 and the gate 502 cover part of each active column D in sequence, and the remaining portion of each active column D serves as a source or a drain of a transistor.

In some embodiments, the bottom of each gap between active columns D is filled with an insulating material 504, and a portion of the active column located at the insulating material 504 is used for forming a drain or a source of the semiconductor structure 50.

In some embodiments, the semiconductor structure further includes an embedded bit line structure (not shown in the figure) located at the bottom of each active column and a capacitance structure (not shown in the figure) located at the top surface of each active column.

It should be noted that the working principle of the semiconductor structure provided by the embodiments of the disclosure is similar to that of the semiconductor structure with the planar gate structure in the above embodiment, and will not be described in detail here.

In the semiconductor structure provided by the embodiments of the disclosure, given that the gate dielectric layer at least includes the isolation layer made of the polarization material capable of spontaneous polarization, and the isolation layer can generate an additional polarization electric field, the polarization electric field makes it possible for electrons or holes enter the charge trapping layer more easily. As a result, the programming voltage and erasing voltage of the semiconductor structure can be reduced, thus the semiconductor device with the low working voltage, low power consumption and high reliability can be provided.

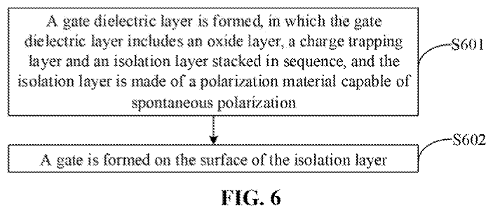

In addition, embodiments of the disclosure also provide a method for forming a semiconductor structure. FIG. 6 is a flowchart of the method for forming a semiconductor structure provided by the embodiments of the disclosure. As shown in FIG. 6, the method for forming a semiconductor structure includes S601 and S602.

At S601, a gate dielectric layer is formed, in which the gate dielectric layer includes an oxide layer, a charge trapping layer and an isolation layer stacked in sequence, and the isolation layer is made of a polarization material capable of spontaneous polarization.

At S602, a gate is formed on the surface of the isolation layer.

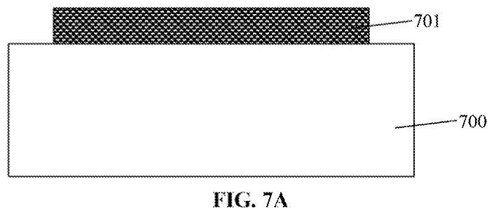

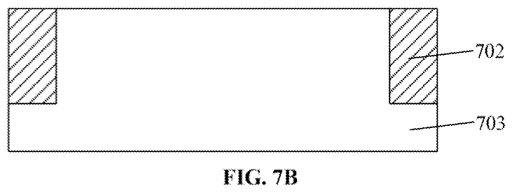

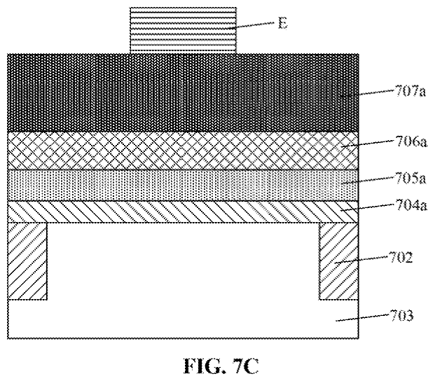

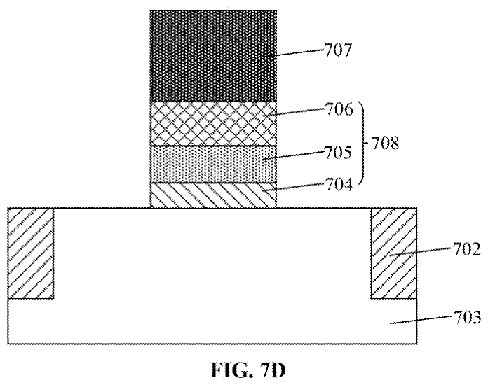

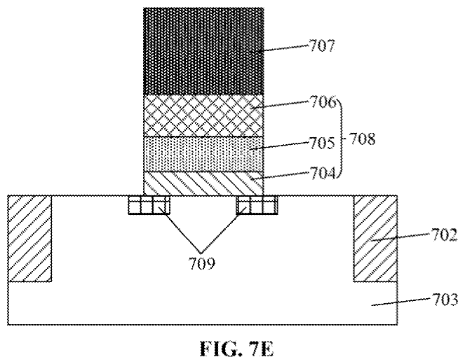

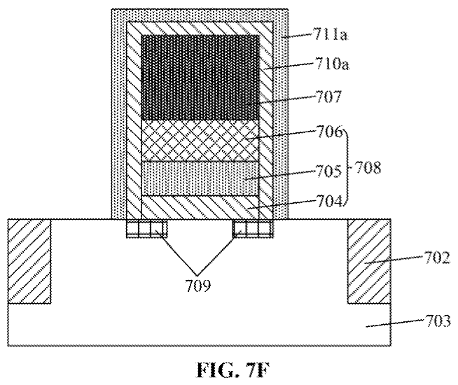

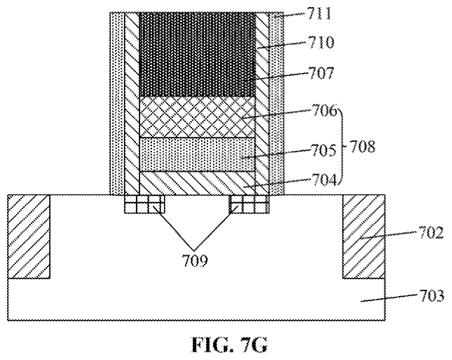

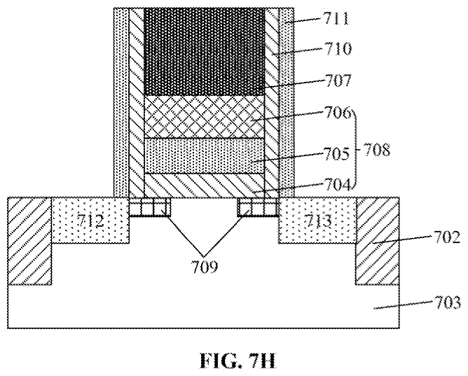

In some embodiments, the gate may be formed on the surface of a well region. FIGS. 7A to 7H are schematic structural diagrams of formation procedure of the semiconductor provided by the embodiments of the disclosure, and the detailed formation process of the semiconductor structure in the embodiments of the disclosure will be described below with reference to FIGS. 7A to 7H.

In the embodiments of the disclosure, the gate is formed on the surface of the well region, and the well region may be formed by S6011, S6012 and S6013.

At S6011, a semiconductor substrate is provided, and a patterned photoresist layer is formed on the surface of the semiconductor substrate.

As shown in FIG. 7A, the patterned photoresist layer 701 is formed on the surface of the semiconductor substrate 700. It should be noted that the semiconductor substrate 700 provided by the embodiments of the disclosure is a substrate doped with N-type ions or P-type ions.

At S6012, the semiconductor substrate is etched by utilizing the patterned photoresist layer to form a plurality of etching trenches.

At S6013, an insulating material is filled in each etching trench to form shallow trench isolation regions and a well region between two adjacent ones of the shallow trench isolation regions.

As shown in FIG. 7B, the semiconductor substrate 700 is etched by utilizing the patterned photoresist layer 701 to form two etching trenches, and the two etching trenches are filled with the insulating material to form the shallow trench isolation regions 702 and a well region 703 between two adjacent ones of the shallow trench isolation regions 702.

In the embodiments of the disclosure, the gate dielectric layer and the gate may be formed by S6014 and S6015.

At S6014, an oxide material, a charge trapping material, the polarization material and a gate material are deposited on the surface of the well region from bottom to top in sequence, and respectively form an initial oxide layer, an initial charge trapping layer, an initial isolation layer and an initial gate.

In the embodiments of the disclosure, the oxide material may be a high-k oxide material, for example, silicon oxide or hafnium oxide. The charge trapping material may be any material with trapping traps, for example, silicon nitride. The polarization material may include a ferroelectric oxide, a ferroelectric fluoride, a ferroelectric semiconductor material, a doped ferroelectric oxide, a polymer ferroelectric material or any combination thereof. The gate material may include tungsten, cobalt, copper, aluminum, polysilicon, doped silicon, a silicide, titanium nitride or any combination thereof. In the embodiments of the disclosure, the initial oxide layer, the initial charge trapping layer, the initial isolation layer and the initial gate may be formed by any suitable deposition process, for example, a chemical vapor deposition (CVD) process, a physical vapor deposition (PVD) process, an atomic layer deposition (ALD) process, a spin coating process or a coating process.

As shown in FIG. 7C, the initial oxide layer 704a, the initial charge trapping layer 705a, the initial isolation layer 706a and the initial gate 707a are formed on the surface of the well region 703 in sequence.

At S6015, the initial gate, the initial isolation layer, the initial charge trapping layer and the initial oxide layer are etched in sequence by utilizing a mask plate with a preset window, so as to form the gate, the isolation layer, the charge trapping layer and the oxide layer.

As shown in FIGS. 7C and 7D, the initial gate 707a, the initial isolation layer 706a, the initial charge trapping layer 705a and the initial oxide layer 704a are etched in sequence by utilizing the preset mask E, so as to form the gate 707, the isolation layer 706, the charge trapping layer 705 and the oxide layer 704. The isolation layer 706, the charge trapping layer 705 and the oxide layer 704 together form the gate dielectric layer 708 of the semiconductor structure.

In some embodiments, the method for forming a semiconductor structure further includes: prior to forming the gate dielectric layer and the gate, forming a sacrificial oxide layer on the surface of each well region by a thermal oxidation process to capture residual ions on the surface of each well region; and removing the sacrificial oxide layer by a wet etching process.

The thermal oxidation process is a process in which the well region is placed in a high temperature so that a thin layer of silicon material of the surface of the well region is oxidized into silicon dioxide. The residual ions include phosphorus ions (P−) produced when forming N wells or boron ions (B+) produced when forming P wells. In the embodiments of the disclosure, the sacrificial oxide layer can reduce defects of the surface of the well region, improve the formation accuracy of the initial oxide layer, thereby improving the property of the semiconductor structure.

In some embodiments, after forming the gate, the method for manufacturing a semiconductor structure further includes S6016 and S6017.

At S6016, part of the well region is doped with ions of a preset type to form a lightly doped drain implanted region.

As shown in FIG. 7E, part of the well region 703 is implanted with arsenic ions or boron ions to form the lightly doped drain implanted region 709 of a low-energy.

At S6017, a spacer structure is formed on sidewalls of the gate dielectric layer and the gate, in which part of the spacer structure is located on the surface of the lightly doped drain implanted region.

In some embodiments, the spacer structure includes a first spacer layer and a second spacer layer outside the first spacer layer. S6017 may include the following operations.

A first initial spacer layer and a second initial spacer layer are formed in sequence on the surface of the well region, the sidewall of the gate dielectric layer, the sidewall and a top of the gate.

The first initial spacer layer may be a silicon oxide layer or a low-k material layer, and the material of the second initial spacer layer may be the insulating material, for example, silicon nitride. In the embodiments of the disclosure, the first initial spacer layer and the second initial spacer layer may be formed by any suitable deposition process.

As shown in FIG. 7F, the first initial spacer layer 710a and the second initial spacer layer 711a are formed in sequence on the surface of the well region 703, the sidewall of the gate dielectric layer 708, the sidewall and the top of the gate 707.

The first initial spacer layer and the second initial spacer layer are etched so that portions of the first initial spacer layer and the second initial spacer layer located on the sidewalls of the gate dielectric layer and the gate are retained to form the first spacer layer and the second spacer layer. The first spacer layer is located on the surface of the lightly doped drain implanted region.

In the embodiments of the disclosure, the first initial spacer layer 710a and the second initial spacer layer 711a in FIG. 7F may be etched by a dry etching process or a wet etching process so that portions of the first initial spacer layer 710a and the second initial spacer layer 711a located on the sidewalls of the gate dielectric layer 708 and the gate 707 are retained to form the first spacer layer 710 and the second spacer layer 711. The first spacer layer 710 is located on the surface of the lightly doped drain implanted region 709.

In some embodiments, after forming the spacer structure, the method for manufacturing a semiconductor structure further includes S6018.

At S6018, a source and a drain outside the lightly doped drain implanted region are formed.

As shown in FIG. 7H, the source 712 and the drain 713 are formed by an ion doping process performed on the well region outside the lightly doped drain implanted region 709.

In some embodiments, after the source and drain are formed, the method for manufacturing a semiconductor structure further includes an operation that a metal interconnection layer is formed on the surface of the well region with the gate, the source and the drain.

In the embodiments of the disclosure, a process of forming the metal interconnection layer is similar to a process of forming a metal interconnection layer in a standard CMOS process, and will not be described in detail here.

In some embodiments, the gate may also be formed in a gate trench in the well region. The dielectric layer and the gate may be formed by S1, S2 and S3.

At S1, an oxide material, a charge trapping material and a polarization material are deposited in sequence on an inner wall of the gate trench to form an initial gate dielectric layer.

The polarization material may include a ferroelectric oxide, a ferroelectric fluoride, a ferroelectric semiconductor material, a doped ferroelectric oxide, a polymer ferroelectric material or any combination thereof.

At S2, a gate material is deposited in the gate trench with the initial gate dielectric layer to form an initial gate.

At S3, the initial gate dielectric layer and the initial gate are etched back to expose part of the inner wall of the gate trench, and the gate dielectric layer and the gate are formed.

In some embodiments, after the gate and the gate dielectric layer are formed in the gate trench, the method for manufacturing a semiconductor structure further includes S4.

At S4, a gate insulation layer is formed on the surfaces of the gate dielectric layer and the gate by a deposition process, in which a top surface of the gate insulation layer is flush with that of a well region.

In some embodiments, the gate may also be formed around each active column in a well region. The dielectric layer and the gate may also be formed by S01, S02, S03 and S04.

At S01, the well region is etched to form a plurality of active columns arranged in an array.

At S02, an oxide material, a charge trapping material and a polarization material are deposited in sequence on the sidewall of each active column from inside to outside to form an initial gate dielectric layer.

The polarization material may include a ferroelectric oxide, a ferroelectric fluoride, a ferroelectric semiconductor material, a doped ferroelectric oxide, a polymer ferroelectric material or any combination thereof.

At S03, a gate material is deposited outside the initial gate dielectric layer to form an initial gate.

At S04, the initial gate dielectric layer and the initial gate are etched back to expose part of each active column, and the gate dielectric layer and the gate are formed.

The forming procedure of the semiconductor structure provided by the embodiments of the disclosure is similar to that of the semiconductor structure provided by the above-mentioned embodiments. For the technical features not disclosed in detail in the embodiment of the disclosure, please refer to the above-mentioned embodiment for understanding, and they will not be repeated here.

The method for manufacturing a semiconductor structure provided by the disclosed embodiment has a process flow similar to that of a standard CMOS process, a novel semiconductor device with a low working voltage, low power consumption and high reliability can be manufactured easily and quickly by the method.

In several embodiments provided by this disclosure, it should be understood that the disclosed devices and methods may be implemented in a non-target way. The device embodiments described above are only illustrative. For example, the division of the units is only a logical function division. In actual implementation, there may be other division means. For example, a plurality of units or components may be combined, or may be integrated into another system, or some features may be ignored, or not implemented. In addition, the components shown or discussed are coupled to each other, or directly coupled.

The unit described above as separated components may or may not be physically separated. The component shown as a unit may or may not be a physical unit, that is, it may be located in one place or distributed to a plurality of network units. Some or all of the units may be selected according to actual needs to achieve the purpose of the solution in the embodiment.

The features disclosed in several method or device embodiments provided in this disclosure may be arbitrarily combined as long as there is no conflict to obtain a new method or device embodiment.

The above are only some embodiments of the embodiments of the disclosure, but the protection scope of the embodiments of the disclosure is not limited to this. Any change or substitution that is easily thought of by a person familiar with the art should be covered within the protection scope of the embodiments of the disclosure. Therefore, the protection scope of the embodiments of the present disclosure should be subject to the protection scope of the claims.

### INDUSTRIAL PRACTICABILITY

A semiconductor structure and a method for manufacturing the semiconductor structure are provided by embodiments of the disclosure, in which the semiconductor structure includes a gate dielectric layer and a gate located on a surface of the gate dielectric layer. The gate dielectric layer includes an oxide layer, a charge trapping layer and an isolation layer stacked in sequence, in which the isolation layer is made of a polarization material capable of spontaneous polarization, and the gate is located on a surface of the gate isolation layer. Since the gate dielectric layer of the semiconductor structure provided by the embodiment of the disclosure at least includes the isolation layer made of the polarization material capable of spontaneous polarization, and the isolation layer can generate an additional polarization electric field, which makes it possible for electrons or holes enter the charge trapping layer more easily. Thus, the embodiment of the disclosure can provide a semiconductor device with a low working voltage, low power consumption and high reliability.

What is claimed is:

1. A semiconductor structure, comprising:
a gate dielectric layer; and
a gate located on a surface of the gate dielectric layer,
wherein the gate dielectric layer comprises an oxide layer, a charge trapping layer and an isolation layer stacked in sequence, and the isolation layer is made of a polarization material capable of spontaneous polarization.

2. The semiconductor structure according to claim 1, wherein the polarization material comprises at least one of a ferroelectric oxide, a ferroelectric fluoride, a ferroelectric semiconductor material, a doped ferroelectric oxide or a polymer ferroelectric material.

3. The semiconductor structure according to claim 1, wherein a thickness of the isolation layer is greater than 1 nanometer.

4. The semiconductor structure according to claim 1, wherein the oxide layer is a high-k material layer, and a material of the oxide layer comprises at least one of hafnium oxide or silicon oxide.

5. The semiconductor structure according to claim 1, wherein a material of the charge trapping layer comprises silicon nitride.

6. The semiconductor structure according to claim 1, wherein the semiconductor structure further comprises a spacer structure located on sidewalls of the gate dielectric layer and the gate, and wherein the spacer structure comprises a first spacer layer and a second spacer layer outside the first spacer layer.

7. The semiconductor structure according to claim 6, wherein a material of the first spacer layer is silicon oxide or a low-k material, and a material of the second spacer layer is an insulating material.

8. The semiconductor structure according to claim 1, wherein the semiconductor structure further comprises a substrate comprising a plurality of well regions, each of the well regions has a source and a drain of a transistor, and wherein the gate dielectric layer is located on an upper surface of the substrate and between the source and the drain.

9. The semiconductor structure according to claim 1, wherein the semiconductor structure further comprises a substrate comprising a plurality of well regions, each of the well regions has a source and a drain of a transistor and has at least one gate trench;
wherein the gate is located in the gate trench, and the gate dielectric layer is located between the gate and the gate trench, and wherein a thickness of the gate is smaller than a thickness of the gate trench in a direction perpendicular to the substrate.

10. The semiconductor structure according to claim 9, wherein the semiconductor structure further comprises a gate insulation layer on surfaces of the gate and the gate dielectric layer, and wherein a top surface of the gate insulation layer is flush with a top surface of a well region.

11. The semiconductor structure according to claim 1, wherein the semiconductor structure further comprises a plurality of well regions, and each of the well regions comprises a plurality of active columns isolated from each other;
and wherein the gate dielectric layer and the gate annularly cover part of an active column in sequence, and remaining part of the active column serves as a source or a drain of a transistor.

12. The semiconductor structure according to claim 11, wherein a top surface of the gate dielectric layer is flush with a top surface of the gate, and a top surface of the active column is beyond the top surface of the gate dielectric layer.

13. A method for manufacturing a semiconductor structure, comprising:
forming a gate dielectric layer, wherein the gate dielectric layer comprises an oxide layer, a charge trapping layer and an isolation layer stacked in sequence, and the isolation layer is made of a polarization material capable of spontaneous polarization; and
forming a gate on a surface of the isolation layer.

14. The method according to claim 13, wherein the gate is formed on a surface of a well region, and the gate dielectric layer and the gate are formed by:
depositing an oxide material, a charge trapping material, the polarization material and a gate material in sequence on the surface of the well region from a bottom to a top to respectively form an initial oxide layer, an initial charge trapping layer, an initial isolation layer and an initial gate; and
etching the initial gate, the initial isolation layer, the initial charge trapping layer and the initial oxide layer in sequence by utilizing a mask plate with a preset window to form the gate, the isolation layer, the charge trapping layer and the oxide layer.

15. The method according to claim 14, further comprising: before forming the gate dielectric layer and the gate,
forming a sacrificial oxide layer on the surface of each of well regions by a thermal oxidation process; and
removing the sacrificial oxide layer by a wet etching process.

16. The method according to claim 13, wherein the gate is formed in a gate trench of a well region, and the gate dielectric layer and the gate are formed by:
depositing an oxide material, a charge trapping material and the polarization material in sequence on an inner wall of the gate trench to form an initial gate dielectric layer;
depositing a gate material in the gate trench with the initial gate dielectric layer to form an initial gate; and
etching back the initial gate dielectric layer and the initial gate to expose part of the inner wall of the gate trench and form the gate dielectric layer and the gate.

17. The method according to claim 16, further comprising:
depositing and forming a gate insulation layer on surfaces of the gate dielectric layer and the gate, wherein a top surface of the gate insulation layer is flush with a top surface of the well region.

18. The method according to claim 13, further comprising:
forming a first spacer layer and a second spacer layer in sequence on sidewalls of the gate dielectric layer and the gate, wherein the first spacer layer and the second spacer layer form a spacer structure.

19. The method according to claim 13, wherein the gate is formed around each of active columns in a well region, and the gate dielectric layer and the gate are formed by:
depositing an oxide material, a charge trapping material and the polarization material in sequence on a sidewall of each of the active columns to form an initial gate dielectric layer;
depositing a gate material on an outside of the initial gate dielectric layer to form an initial gate; and
etching back the initial gate dielectric layer and the initial gate to expose part of each of the active columns and form the gate dielectric layer and the gate.

20. The method according to claim 13, wherein the polarization material comprises at least one of a ferroelectric oxide, a ferroelectric fluoride, a ferroelectric semiconductor material, a doped ferroelectric oxide or a polymer ferroelectric material.
